(19) United States
(12) Patent Application Publication
(10) Pub. No.: US 2011/0079175 A1
(43) Pub. Date: Apr. 7, 2011

(54) IMAGE SENSOR AND METHOD FOR MANUFACTURING THE SAME

(76) Inventors: Il-Soo Choi, Gumi-si (KR); Ji-Hun Moon, Gumi-si (KR); Bong-Woo Kim, Gumi-si (KR); Do-Yeon Kim, Dong-gu (KR)

(21) Appl. No.: 12/899,517

(22) Filed: Oct. 6, 2010

(30) Foreign Application Priority Data
Oct. 6, 2009 (KR) 10-2009-0094507

(51) Int. Cl. C30B 15/10; C03B 19/09

(52) U.S. Cl. 117/208; 65/30.1

(57) ABSTRACT

Provided are a quartz crucible and a method of manufacturing the quartz crucible. The quartz crucible is used in a single crystal growth apparatus. The quartz crucible comprises an inner layer including silica, and an outer layer including silica disposed outside the inner layer to surround the inner layer, wherein nitrogen is added in the silica of the outer layer.

### CROSS-REFERENCE TO RELATED APPLICATION

This application claims the priority benefit of Korean patent application number 10-2009-0094507 filed Oct. 6, 2009, the disclosure of which is incorporated herein by reference.

### BACKGROUND OF THE INVENTION

1. Field of the Invention

The present disclosure relates to a quartz crucible and a method of manufacturing the quartz crucible.

2. Description of the Related Art

In a single crystal growth process according to a Czochralski (Cz) method, a seed is immersed in silicon melt accommodated in a quartz crucible, and then, a seed cable is rotated and slowly moved upward to grow a single crystal ingot through a solid-liquid interface.

A single crystal growth apparatus for performing the Czochralski method typically includes a quartz crucible, a crucible support surrounding and supporting the quartz crucible, a heater disposed outside the crucible support to supply radiant heat to the quartz crucible, a heat shield disposed between a growing single crystal ingot and the quartz crucible to surround the single crystal ingot and block a heat flow emitted upward from silicon melt, and a supporter supporting the lower portion of the crucible support.

Especially, the quartz crucible of the single crystal growth apparatus is a container that melts a poly crystal silicon source material to form silicon melt, and thus, the quartz crucible is required to have small impurity content and a small physical deformation at high temperature.

Typically, a quartz crucible includes a transparent inner layer having no bubble, and an outer layer disposed outside the inner layer. An accommodation space is disposed at the inside of the inner layer, and the quartz crucible has an open upper surface.

When a quartz crucible is maintained for a long time at a high temperature ranging from about 1450 to 1500° C., the quartz crucible is softened, so that its upper portion is bent to cause a serious yield decrease. For example, as illustrated in FIG. 1, a portion A of a rim R′ of a quartz crucible deformed by high temperature is further bent to the inside of the crucible than the rim R in a normal state to disturb a silicon single crystal growth process.

As illustrated in FIG. 2, when the upper portion of a quartz crucible 10 is bent (indicated by circles), the quartz crucible 10 and a heat shield 13 interfere with each other, and a process condition changes, so that it is difficult to perform a process. Thus, silicon melt in the quartz crucible 10 is wasted. At this point, it is difficult to solidify the silicon melt and take the solidified silicon out of a growth apparatus because a crucible support 11 surrounding the quartz crucible 10 or a supporter 14 supporting the quartz crucible 10 may be broken by volume expansion of silicon solid.

Thus, to take silicon melt out of a growth apparatus, a very short ingot is grown several times, and the amount of the silicon melt is reduced little by little, and then, residual melt remaining in the quartz crucible 10 is solidified. These processes take a long time, and are expensive and dangerous, which may cause an accident.

When the upper portion of the quartz crucible 10 is bent, and the quartz crucible 10 contacts the heat shield 13, graphite particles are generated. The graphite particles fall on the surface of the silicon melt and damage a growing single crystal, and thus, breaking a single crystal structure.

In addition, when a quartz crucible is maintained at high temperature for a long time, a portion of the side surface of the quartz crucible may sag as illustrated in FIG. 3. In this case, a temperature distribution symmetry of the quartz crucible is broken, and thus, a single crystal structure is broken by a thermal shock.

In addition, to grow a high quality single crystal, hydroxyl groups (OH—) are typically introduced to silica such that an impurity concentration is maintained at 100 ppb (parts per billion) or less in a process of forming an inner surface of a quartz crucible. At this point, the viscosity of the crucible is lowered, so that the crucible seriously sags.

### SUMMARY OF THE CLAIMED INVENTION

Embodiments provide a high strength quartz crucible including an outer layer with an improved composition to prevent bending and sagging of a crucible body due to a high temperature process for growing a single crystal, and a method of manufacturing the high strength quartz crucible.

In one embodiment, a quartz crucible used in a single crystal growth apparatus comprises: an inner layer including silica; and an outer layer including silica disposed outside the inner layer to surround the inner layer, wherein nitrogen is added in the silica of the outer layer.

In another embodiment, a method of manufacturing a quartz crucible comprises: forming an outer layer by putting natural silica sand in a crucible mold, and then, melting the natural silica sand; and forming an inner layer on an inside of the outer layer by putting synthetic silica sand in the crucible mold, and then, melting the synthetic silica sand, wherein nitrogen is added in the forming of the outer layer.

The details of one or more embodiments are set forth in the accompanying drawings and the description below. Other features will be apparent from the description and drawings, and from the claims.

### BRIEF DESCRIPTION OF THE DRAWINGS

FIG. 1 is a plan view illustrating bending of the upper portion of a quartz crucible in the related art.

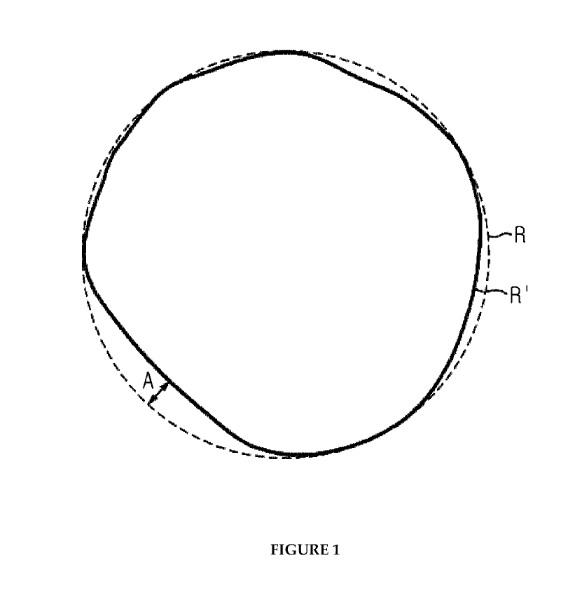

FIG. 2 is a cross-sectional view illustrating bending of the upper portion of a quartz crucible in a single crystal growth apparatus in the related art.

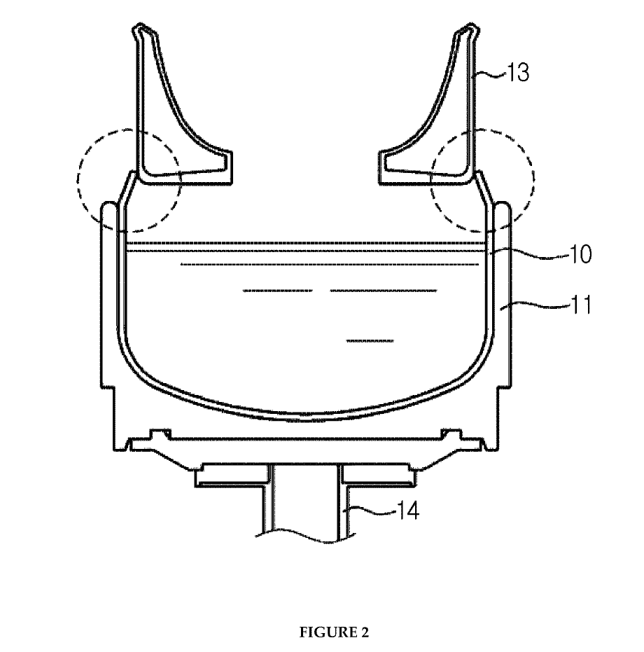

FIG. 3 is an image illustrating sagging of a side surface of a quartz crucible in the related art.

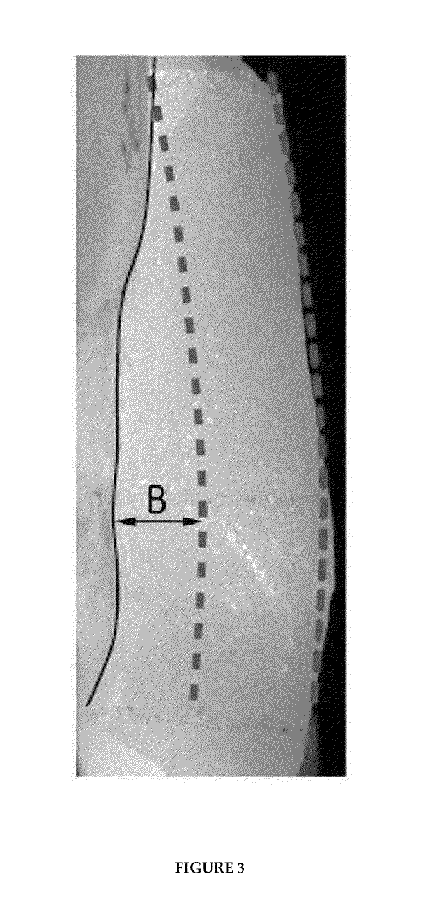

FIG. 4 is a schematic view illustrating a single crystal growth apparatus according to an embodiment of the present invention.

FIG. 5 is a cross-sectional view illustrating a high strength quartz crucible according to an embodiment of the present invention.

FIG. 6 is a flowchart illustrating a process of manufacturing a high strength quartz crucible according to an embodiment of the present invention.

### DETAILED DESCRIPTION

In the description of embodiments, it will be understood that when a wafer, an apparatus, a chuck, a member, a part, a region, or a surface is referred to as being ‘on/over’ or ‘under’ another wafer, apparatus, chuck, member, part, region, or surface, it can be directly on the another one, or intervening ones may also be present. Further, the reference about on and ‘under’ each layer will be made on the basis of drawings.

In the drawings, the thickness or size of each layer is exaggerated, omitted, or schematically illustrated for convenience in description and clarity. Also, the size of each element does not entirely reflect an actual size.

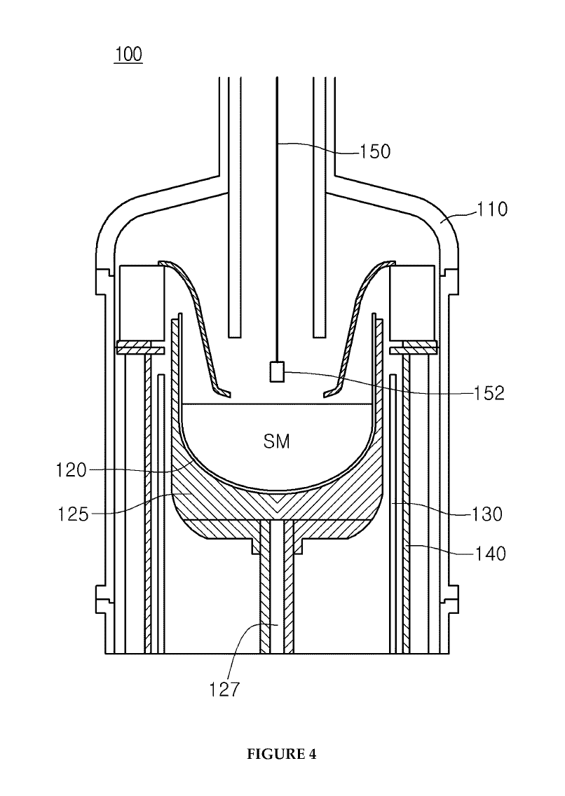

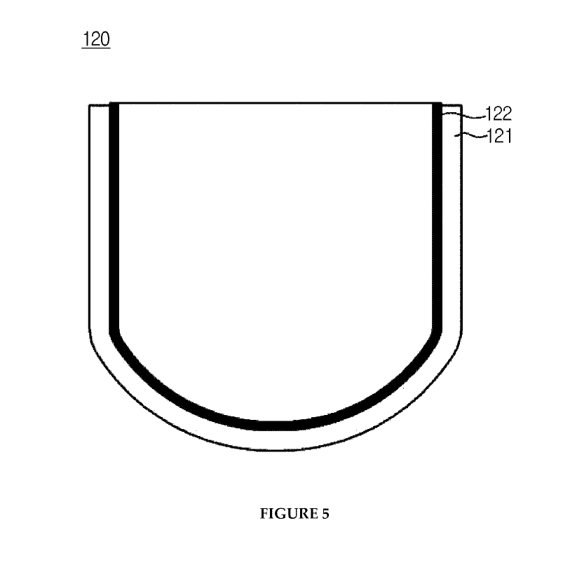

FIG. 4 is a schematic view illustrating a single crystal growth apparatus according to an embodiment. FIG. 5 is a cross-sectional view illustrating a high strength quartz crucible according to an embodiment.

Referring to FIG. 5, a high strength quartz crucible 120 according to the current embodiment may include a transparent inner layer 122 without a bubble, an opaque outer layer 121 containing nitrogen, and an accommodation space disposed at the inside of the inner layer 122. The high strength quartz crucible 120 may have an open upper surface.

The high strength quartz crucible 120 is used in a growth apparatus that grows a silicon single crystal using a Czochralski (Cz) method. Silicon melt can be accommodated in the high strength quartz crucible 120.

Referring to FIG. 4, a single crystal growth apparatus will now be described according to the current embodiment.

A silicon single crystal growth apparatus 100 according to the current embodiment may include a chamber 110, the crucible 120, a heater 130, and an elevation member 150.

For example, the single crystal growth apparatus 100 may include the chamber 110, the crucible 120 disposed in the chamber 110 and accommodating silicon melt, the heater 130 disposed in the chamber 110 and heating the crucible 120, and the elevation member 150 having an end coupled with a seed crystal 152.

The chamber 110 provides a space for predetermined processes in which a single crystal ingot for a silicon wafer is grown to be used in an electronic part such as a semiconductor.

A radiation insulator 140 may be installed on an inner wall of the chamber 110 to prevent heat from being emitted from the heater 130 to a side wall of the chamber 110.

In the current embodiment, various parameters such as a pressure condition in the rotating crucible 120 can be adjusted to control an oxygen concentration while a silicon single crystal is grown. For example, argon gas is injected in a chamber of a single crystal growth apparatus and is discharged to the lower side to control an oxygen concentration.

The crucible 120 may be disposed in the chamber 10 to contain silicon melt SM, and be formed of quartz. A crucible support 125 formed of graphite may be disposed outside the crucible 120 to support the crucible 120. The crucible support 125 is fixed to a rotation shaft 127 that is rotated by a driving member (not shown) to rotate and vertically move the crucible 120, so that a solid-liquid interface can be maintained at the same height.

The heater 130 may be disposed in the chamber 110 to heat the crucible 120. For example, the heater 130 may be cylindrical to surround the crucible support 125. The heater 130 melts high purity poly crystal silicon mass stacked in the crucible 120 to form silicon melt.

In one embodiment, the Czochralski method is used to grow a silicon single crystal ingot. In the Czochralski method, a single crystalline seed crystal is immersed in silicon melt, and then, is slowly pulled up to grow a crystal.

According to the Czochralski method, a necking process of growing a thin and long crystal from a seed crystal, a shouldering process of growing a crystal in a radial direction to have a target diameter, a body growing process of growing the crystal to have a constant diameter, and a tailing process of slowly decreasing the diameter of the crystal to remove the crystal from the silicon melt are sequentially performed to complete a single crystal growth.

The inner layer 122 of the crucible 120 may be constituted by a transparent synthetic silica (SiO₂) layer in a high purity state without a bubble from the inner surface of the crucible 120 to a depth of about 10 mm.

An impurity concentration of the inner layer 122 may be about 100 ppb or less to grow a high quality single crystal, but the present disclosure is not limited thereto.

The outer layer 121 of the crucible 120 may be constituted by a bubble-containing natural silica layer to improve durability and suppress a melt vibration.

Since the outer layer 121 is opaque because of bubbles, the outer layer 121 can spread heat radiation.

A nitrogen (N) component is added in the outer layer 121 to increase physical properties such as strength, durability, and viscosity. For example, since an Si—N bond has stronger covalent bond characteristics than an Si—O bond, the outer layer 121 is high in glass transition point, density, Vicker hardness, viscosity, elasticity, and chemical durability, and is low in coefficient of thermal expansion.

Especially, physical properties such as hardness, viscosity, or elasticity, which greatly affect bending or sagging of a quartz crucible, can be significantly improved when a nitrogen content ranges from about 1 to 15 atomic %.

According to an embodiment, since a high strength quartz crucible configured as described above includes the outer layer 121, although a heater applies high temperature radiant heat to the quartz crucible in a single crystal growth process, thermal, mechanical, and chemical stability can be maintained, so that, bending or sagging of the upper portion of the crucible can be prevented.

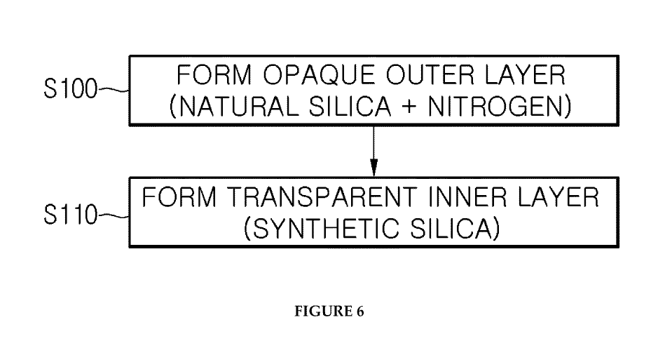

FIG. 6 is a flowchart illustrating a process of manufacturing a high strength quartz crucible according to an embodiment.

The high strength quartz crucible may be manufactured by disposing a crucible mold corresponding to the quartz crucible in a chamber, and then, by performing an argon (Ar) fusion process using silica sand as a source material to sequentially form the outer layer 121 and the inner layer 122.

For example, when the outer layer 121 is formed in operation S100, natural silica sand is put in the crucible mold, and nitrogen providing stronger covalent bond characteristics is added, the natural silica sand and the nitrogen are melted to form the bubble-containing transparent outer layer 121.

At this point, the nitrogen may be added with a concentration ranging from about 1 to about 15 atomic % in Ar atmosphere with a concentration ranging from about 1 to about 50%.

According to another embodiment, silicon nitride (Si₃N₄), aluminum nitride (AlN), calcium nitride (Ca₃N₂), or lithium nitride (Li₃N) may be mixed with the natural silica sand to add nitrogen with a concentration ranging from about 1 to about 15 atomic %.

Next, when the inner layer 122 is formed in operation S110, synthetic silica sand may be put in the crucible mold and melted to form the transparent inner layer 122 having a thickness ranging from about 3 to about 15 mm on the inside of the outer layer 121. The inner layer 122 can have a high purity structure without a bubble from the inner surface of the crucible down to a depth of about 10 mm by controlling a gas flow and exhausting.

According to the current embodiment, to set an impurity concentration of the inner layer 122 to about 100 ppb or less for growing a high quality single crystal, hydroxyl groups (OH—) may be introduced at a concentration ranging from about 30 to about 100 ppma to the synthetic silica sand while the inner layer 122 is formed.

Although the hydroxyl groups (OH—) are introduced, the nitrogen component included in the outer layer 121 maintains the quartz crucible in high viscosity and elasticity state, and thus, the sagging is prevented even under a long-time and high temperature condition.

The quartz crucible and the method of manufacturing the same according to the embodiments provide the physical properties such as high strength, durability, and viscosity to the outer layer of the quartz crucible, so that physical deformations (bending, sagging, and exfoliation) of the upper portion of the quartz crucible due to high temperature heat can be prevented, and the inner layer can be maintained at an impurity concentration of about 100 ppb or less, and thus, a high quality single crystal can be manufactured.

In addition, when the embodiments are applied to an ingot growth process using the Czochralski method, the yield of a single crystal can be improved, and a friction between the quartz crucible and a heat shield is prevented, thereby preventing an accident.

In addition, when the embodiments are applied to an ingot growth process using the Czochralski method, the yield of a single crystal can be improved, but the present disclosure is not limited thereto.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A quartz crucible used in a single crystal growth apparatus, the quartz crucible comprising:
an inner layer including silica; and
an outer layer including silica disposed outside the inner layer to surround the inner layer, wherein nitrogen is added in the silica of the outer layer.

2. The quartz crucible of claim 1, wherein the inner layer includes a transparent layer.

3. The quartz crucible of claim 1, wherein the outer layer includes an opaque layer.

4. The quartz crucible of claim 1, wherein the inner layer includes a synthetic silica layer without a bubble from an inner surface of the quartz crucible down to a depth of about 10 mm.

5. The quartz crucible of claim 1, wherein the outer layer includes a natural silica layer having bubbles.

6. The quartz crucible of claim 1, wherein the outer layer has a nitrogen content ranging from about 1 atomic % to about 15 atomic %.

7. The quartz crucible of claim 1, wherein the inner layer has an impurity concentration of 100 ppb or less.

8. A method of manufacturing a quartz crucible, the method comprising:
forming an outer layer by placing natural silica sand in a crucible mold,
melting the natural silica sand in the crucible mold; and
forming an inner layer on an inside of the outer layer by placing synthetic silica sand in the crucible mold; and
melting the synthetic silica sand, wherein nitrogen is added in the forming of the outer layer.

9. The method of claim 8, wherein the inner layer includes a transparent layer, and the outer layer comprises an opaque layer.

10. The method of claim 8, wherein the nitrogen is added with a content ranging from about 1 atomic % to about 15 atomic % in argon (Ar) atmosphere with a concentration ranging from about 1% to about 50% in the forming of the outer layer.

11. The method of claim 8, wherein at least one of silicon nitride (Si₃N₄), aluminum nitride (AlN), calcium nitride (Ca₃N₂), and lithium nitride (Li₃N) is mixed with the natural silica sand in the forming of the outer layer to add the nitrogen with a content ranging from about 1 atomic % to about 15 atomic %.

12. The method of claim 8, wherein the inner layer has a thickness ranging from about 3 mm to about 15 mm in the forming of the inner layer.

13. The method of claim 8, wherein hydroxyl groups (OH—) are introduced with a concentration ranging from about 30 ppma to about 100 ppma to the synthetic silica sand in the forming of the inner layer such that the inner layer has an impurity concentration of 100 ppb or less.
